(19) United States
(12) Patent Application Publication
(10) Pub. No.: US 2021/0111300 A1
(43) Pub. Date: Apr. 15, 2021

(54) THIN FILM DEPOSITION SYSTEMS AND DEPOSITION METHODS FOR FORMING PHOTOVOLTAIC CELLS

(71) Applicant: BEIJING APOLLO DING RONG SOLAR TECHNOLOGY CO., LTD., Bejing (CN)

(72) Inventors: Robel FESSEHATZION, Campbell, CA (US); Ben HICKEY, Redwood City, CA (US); Jochen TITUS, San Jose, CA (US); Dmitry POPLAVSKYY, San Jose, CA (US); Neil MACKIE, Fremont, CA (US)

(21) Appl. No.: 17/066,786

(22) Filed: Oct. 9, 2020

Related U.S. Application Data
(60) Provisional application No. 62/913,467, filed on Oct. 10, 2019.

(51) Int. Cl. H01L 31/18; C23C 14/58; C23C 14/56; C23C 14/06; C23C 14/34

(52) U.S. Cl. CPC H01L 31/18; C23C 14/586; H01L 31/0749; C23C 14/0641; C23C 14/3464; C23C 14/562

(57) ABSTRACT

A thin film deposition system and method for forming photovoltaic cells, the system including a first deposition module including a titanium sputtering target and configured to deposit a titanium precursor layer of a diffusion barrier on the substrate, as the substrate moves through the first deposition module; a second deposition module configured to deposit a first electrode onto the diffusion barrier, as the substrate moves through the second deposition module; and a first connection unit configured to nitride at least a portion of the titanium precursor layer of the diffusion barrier, while the substrate moves though the first connection unit from the first deposition module to the second deposition module.

### BACKGROUND

The present disclosure is directed generally to thin film deposition systems and methods for forming photovoltaic cells. In particular, the systems may include a connection chamber configured nitride a titanium diffusion barrier, while transferring a substrate between adjacent deposition modules, under vacuum conditions.

A “thin-film” photovoltaic material refers to a polycrystalline or amorphous photovoltaic material that is deposited as a layer on a substrate that provides structural support. The thin-film photovoltaic materials are distinguished from single crystalline semiconductor materials that have a higher manufacturing cost. Some of the thin-film photovoltaic materials that provide high conversion efficiency include chalcogen-containing compound semiconductor material, such as copper indium gallium selenide (“CIGS”).

Thin-film photovoltaic cells (also known as solar cells) may be manufactured using a roll-to-roll coating system based on sputtering, evaporation, or chemical vapor deposition (CVD) techniques. A thin foil substrate, such as a foil web substrate, is fed from a roll in a linear belt-like fashion through the series of individual vacuum chambers or a single divided vacuum chamber where it receives the required layers to form the thin-film photovoltaic cells. In such a system, a foil having a finite length may be supplied on a roll. The end of a new roll may be coupled to the end of a previous roll to provide a continuously fed foil layer.

### SUMMARY

According various embodiments, a thin film deposition system configured to form a photovoltaic cell on a moving metal substrate comprises: a first deposition module comprising a titanium sputtering target and configured to deposit a titanium precursor layer of a diffusion barrier on the substrate as the substrate moves through the first deposition module; a second deposition module configured to deposit a first electrode onto the diffusion barrier as the substrate moves through the second deposition module; and a first connection unit configured to nitride at least a portion of the titanium precursor layer, while the substrate moves though the first connection unit from the first deposition module to the second deposition module.

According various embodiments, a sputter deposition method includes depositing a titanium precursor layer onto a front side of a substrate using a first deposition module while moving the substrate through the first deposition module and heating the substrate; transferring the substrate from the first deposition module to a second deposition module using a first connection module configured, while nitriding at least a portion of the titanium precursor layer to form a diffusion barrier by supplying a nitrogen-rich gas to the first connection module; depositing a first electrode onto the diffusion barrier using the second deposition module, while moving the substrate through the second deposition module; and depositing a p-doped semiconductor layer, an n-doped semiconductor layer, and a second electrode onto the first electrode layer, using respective additional deposition modules, while transferring the substrate between the additional deposition modules using additional connection modules configured to maintain vacuum conditions.

According to various embodiments of the present disclosure, provided is a photovoltaic cell comprising: a metal substrate having a front side and a back side; a protective layer disposed on the back side of the substrate; a diffusion barrier comprising titanium nitride disposed on the front side of the substrate; a first electrode comprising a first molybdenum layer, a second molybdenum layer, and a sodium-doped molybdenum layer disposed between the first and second molybdenum layers; a p-doped semiconductor layer disposed on the first electrode; an n-doped semiconductor layer disposed on the p-doped semiconductor layer; and a second electrode disposed on the n-doped semiconductor layer.

### BRIEF DESCRIPTION OF THE DRAWINGS

FIG. 1 is a schematic vertical cross sectional view of a thin-film photovoltaic cell, according to various embodiments of the present disclosure.

FIG. 2 is a schematic top view diagram of an exemplary modular deposition apparatus that can be used to manufacture the photovoltaic cell illustrated in FIG. 1, according to various embodiments of the present disclosure.

FIG. 3 is a perspective view of adjacent deposition modules and the corresponding connection unit of the modular deposition apparatus, when arranged in a non-linear configuration, according to various embodiments of the present disclosure

FIG. 4 is a top view of a chamber of a connection unit configured to nitride a titanium diffusion barrier layer, according to various embodiments of the present disclosure.

FIG. 5 is a block diagram illustrating a sputter deposition method, according to various embodiments of the present disclosure.

### DETAILED DESCRIPTION

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a direct physical contact between a surface of the first element and a surface of the second element.

Ranges can be expressed herein as from “about” one particular value, and/or to “about” another particular value. When such a range is expressed, examples include from the one particular value and/or to the other particular value. Similarly, when values are expressed as approximations, by use of the antecedent “about” or “substantially” it will be understood that the particular value forms another aspect. In some embodiments, a value of “about X” may include values of +/−1% X. It will be further understood that the endpoints of each of the ranges are significant both in relation to the other endpoint, and independently of the other endpoint.

The present disclosure is directed to an apparatus and method for forming photovoltaic devices on a web substrate. In particular, the present disclosure relates to an apparatus and method for selectively depositing layers of a photovoltaic device on a web substrate while reducing substrate deformation. The web substrate typically has a width (i.e., a height of the web substrate for a vertically positioned web substrate, which is perpendicular to the length (i.e., movement direction) of the web substrate) of at least 10 cm, and oftentimes a width of about 1 meters or more, such as 1 to 5 meters. Deposition of a film with a uniform thickness and/or composition as a function of a large web substrate width is a challenge even in a large deposition chamber. Particularly, the web should be as flat (e.g., planar) as possible to promote consistent deposition.

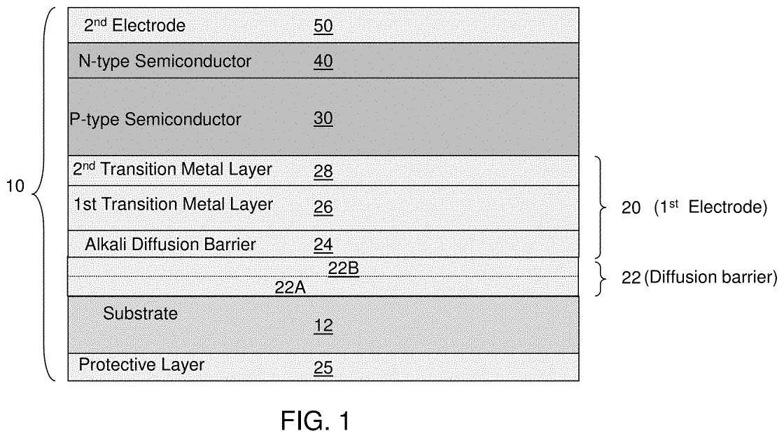

Referring to FIG. 1, a vertical cross-sectional view of a photovoltaic cell 10 (e.g., solar cell) is illustrated. The photovoltaic cell 10 includes a substrate 12, a diffusion barrier 22, a first electrode 20, a p-doped semiconductor absorber layer 30, an n-doped semiconductor layer 40, a second electrode 50, and an optional backside protective layer 25.

The substrate 12 is preferably a flexible, electrically conductive material, such as a metallic foil that is fed into a system of one or more deposition modules as a web for deposition of additional layers thereupon. For example, the conductive substrate 12 can be a sheet of a metal or a metallic alloy such as stainless steel, aluminum, or titanium. In various embodiments, the substrate 12 may be ferromagnetic. If the substrate 12 is electrically conductive, then it may comprise a part of the first (i.e., back side) electrode of the cell 10. Alternatively, the substrate 12 may be an electrically conductive or insulating polymer foil. Still alternatively, the substrate 12 may be a stack of a polymer foil and a metallic foil. The thickness of the substrate 12 can be in a range from 25 microns to 1 mm, although lesser and greater thicknesses can also be employed.

The diffusion barrier 22 may be a conductive layer formed directly on the front surface of the substrate 12, such that the diffusion barrier 22 is disposed between the substrate 12 and the first electrode 20. The diffusion barrier 22 may have a thickness ranging from about 50 nm to about 600 nm, such as from about 100 nm to about 500 nm, or from about 200 nm to about 450 nm.

The diffusion barrier 22 may be formed of a material configured to suppress the diffusion of Cr species from the substrate 12 into the first electrode 20. For example, the diffusion barrier 22 may include a film comprising a metal nitride, such as TiN or the like. In some embodiments, the diffusion barrier 22 comprises a lower titanium layer 22A disposed on the substrate 12 and an upper titanium nitride layer 22B disposed on the lower titanium layer 22A. The lower titanium layer 22A may have a thickness of 50 nm to 250 nm, such as 100 nm to 200 nm, and the upper titanium nitride layer may have a thickness of 50 nm to 250 nm, such as 100 nm to 200 nm. The first electrode 20 may be disposed on the front surface of the diffusion barrier 22.

The first electrode 20 may have a thickness in a range of from 200 nm to 1 micron, although lesser and greater thicknesses can also be employed. The first electrode 20 may comprise any suitable electrically conductive layer, such as a molybdenum layer, or stack of layers. For example, the first electrode 20 may include a stack of molybdenum and sodium and/or oxygen doped molybdenum layers. In particular, the first electrode 20 may include an alkali diffusion barrier 24, a first transition metal layer 26, and a second transition metal layer 28, as described in U.S. Pat. No. 8,134,069, which is incorporated herein by reference in its entirety.

For example, the first transition metal layer 26 may include a molybdenum material layer doped with K and/or Na, i.e., MoKₓ or Mo(Na,K)ₓ, in which x can be in a range from 1.0×10⁻⁶ to 1.0×10⁻², for example, 10²⁰ to 10²³ sodium atoms per cm³. The alkali diffusion barrier 24 and the second transition metal layer 28 may comprise any suitable conductive materials, such as a material independently selected from a group consisting Mo, W, Ta, V, Ti, Nb, Zr, Cr, TiN, ZrN, TaN, VN, V₂N, or combinations thereof.

In some embodiments, while the alkali diffusion barrier 24 may be substantially oxygen free, the first transition metal layer 26 and/or the second transition metal layer 28 may contain oxygen and/or be deposited at a higher pressure than the alkali diffusion barrier layer 24 to achieve a lower density than the alkali diffusion barrier layer 24. For example, the first transition metal layer 26 may include 1-40 at % oxygen, such as 5-20 at % oxygen and 0.01-0.4 at % sodium, and a balance of molybdenum oxide, while the second transition metal layer 28 may contain 1 to 10 atomic percent oxygen, such as from 1 to 5 atomic percent oxygen and 90 to 95 atomic percent molybdenum. Of course, other impurity elements (e.g. lattice distortion elements or the lattice distortion compounds), instead of or in addition to oxygen or compounds thereof (e.g., MoO₂ and/or MoO₃) may be contained in the first transition metal layer 26 and/or the second transition metal layer 28 to reduce the density thereof. For example, sodium may diffuse from the first transition metal layer 26 into the second transition metal layer 28. Thus, layers 26 and 28 are preferably less dense than layer 24 if all three layers are molybdenum-based layers. The second transition metal layer 28 controls the alkali diffusion into the absorber layer 30, based on the thickness, composition, and/or density thereof. The second transition metal layer 28 may also act a nucleation layer for the absorber layer 30.

The alkali diffusion barrier 24 may be in compressive stress and have a thickness greater than that of the second transition metal layer 28. For example, the alkali diffusion barrier 24 may have a thickness of around 100 to 400 nm such as 100 to 200 nm, while the second transition metal layer 28 has a thickness of around 50 to 200 nm such as 50 to 100 nm.

The higher density and greater thickness of the alkali diffusion barrier 24 substantially reduces or prevents alkali diffusion from the first transition metal layer 26 into the substrate 12. On the other hand, the second transition metal layer 28 has a higher porosity than the alkali diffusion barrier 24 and permits alkali diffusion from the first transition metal layer 26 into the p-doped semiconductor absorber layer 30. In these embodiments, alkali metals may diffuse from the first transition metal layer 26, through the lower density second transition metal layer 28, and into the p-doped semiconductor absorber layer 30, during and/or after the step of depositing the at least one p-doped semiconductor layer 30.

Alternatively, the optional alkali diffusion barrier layer 24 and/or optional second transition metal layer 28 may be omitted. When the optional second transition metal layer 28 is omitted, the at least one p-type semiconductor absorber layer 30 is deposited on the first transition metal layer 26, and alkali may diffuse from the first transition metal layer 26 into the at least one p-type semiconductor absorber layer 30 during or after the deposition of the at least one p-type semiconductor absorber layer 30.

The protective layer 25 may have an emissivity greater than 0.25 and a reactivity with a selenium-containing gas that is lower than that of the substrate 12, as described in U.S. Pat. No. 8,115,095, which is incorporated herein, by reference, in its entirety. The protective layer 25 may comprise molybdenum that is intentionally doped by (i.e., alloyed with) at least one of oxygen or nitrogen. Preferably, the protective layer 25 comprises oxygen-containing molybdenum having an oxygen atomic concentration of higher than 10%, such as 15-50%, and/or a nitrogen doped molybdenum having a nitrogen atomic concentration of higher than 10%, such as 15-50%. The protective layer 25 may contain 15-50 atomic percent of a combination of oxygen and nitrogen. In a non-limiting example, the protective layer 25 is a molybdenum oxide layer containing about 70 atomic percent molybdenum and about 30 atomic percent oxygen. A noted above, 10-50% of oxygen (or nitrogen) may be substituted by selenium during the reactive sputtering deposition of CIGS, such that the protective layer 25 contains around 10 atomic percent selenium, around 20 atomic percent oxygen, and around 70 atomic percent molybdenum. Preferably, the protective layer 25 is thick enough such that a portion of the protective layer adjacent to the substrate 12 is substantially free of selenium (having a selenium concentration less than 5 atomic percent).

The p-doped semiconductor layer 30 may include a p-type sodium doped copper indium gallium selenide (CIGS), which functions as a semiconductor absorber layer. The thickness of the p-doped semiconductor layer 30 can be in a range from 1 microns to 5 microns, although lesser and greater thicknesses can also be employed.

The n-doped semiconductor layer 40 may include an n-doped semiconductor material such as CdS, ZnS, ZnSe, or an alternative metal sulfide or a metal selenide. The thickness of the n-doped semiconductor layer 40 is typically less than the thickness of the p-doped semiconductor layer 30, and can be in a range from 30 nm to 100 nm, although lesser and greater thicknesses can also be employed. The junction between the p-doped semiconductor layer 30 and the n-doped semiconductor layer 40 is a p-n junction. The n-doped semiconductor layer 40 can be a material which is substantially transparent to at least part of the solar radiation. The n-doped semiconductor layer 40 is also referred to as a window layer or a buffer layer.

The second (e.g., front side or top) electrode 50 is conductive and optically transparent and may comprise one or more transparent conductive material layers. For example, the second electrode may include a relatively lower resistivity layer formed of ZnO, indium tin oxide (ITO), Al doped ZnO (“AZO”), boron doped ZnO (“BZO”), and an optional relatively higher resistivity layer comprising aluminum zinc oxide (RAZO). The second electrode 50 contacts an electrically conductive part (e.g., a metal wire or trace) of an interconnect, such as an interconnect described in U.S. Pat. No. 8,912,429, issued Dec. 16, 2014, which is incorporated herein by reference in its entirety, or any other suitable interconnect that is used in photovoltaic panels.

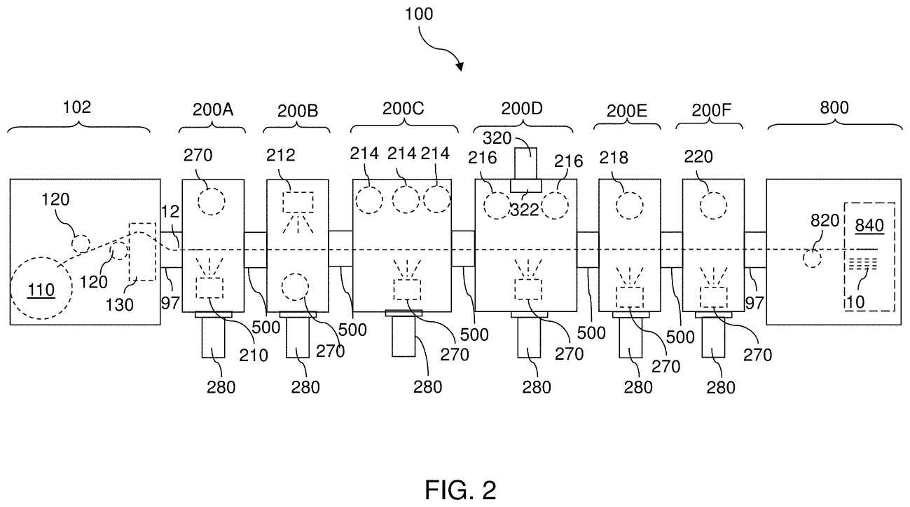

Referring now to FIG. 2, an apparatus 100 for forming the photovoltaic cell 10 illustrated in FIG. 1 is shown. The apparatus 100 is a first exemplary modular deposition apparatus that can be used to manufacture the photovoltaic cell 10 illustrated in FIG. 1. The apparatus 100 includes an input module 102, deposition modules 200A-200F, and an output module 800 that are sequentially connected to accommodate a continuous flow of the substrate 12 in the form of a web foil substrate layer through the apparatus. Deposition modules 200A-200F may comprise sputtering modules as described in U.S. Pat. No. 9,303,316, issued on Apr. 5, 2016, incorporated herein by reference in its entirety, or any other suitable modules. Deposition modules 200A-200F can generate vacuum conditions using respective vacuum pumps 280. The vacuum pumps 280 can provide a suitable level of respective base pressure for each of deposition modules 200A-200F, which may be in a range from 1.0×10⁻⁹ Torr to 1.0×10⁻² Torr, and preferably in range from 1.0×10⁻⁹ Torr to 1.0×10⁻⁵ Torr.

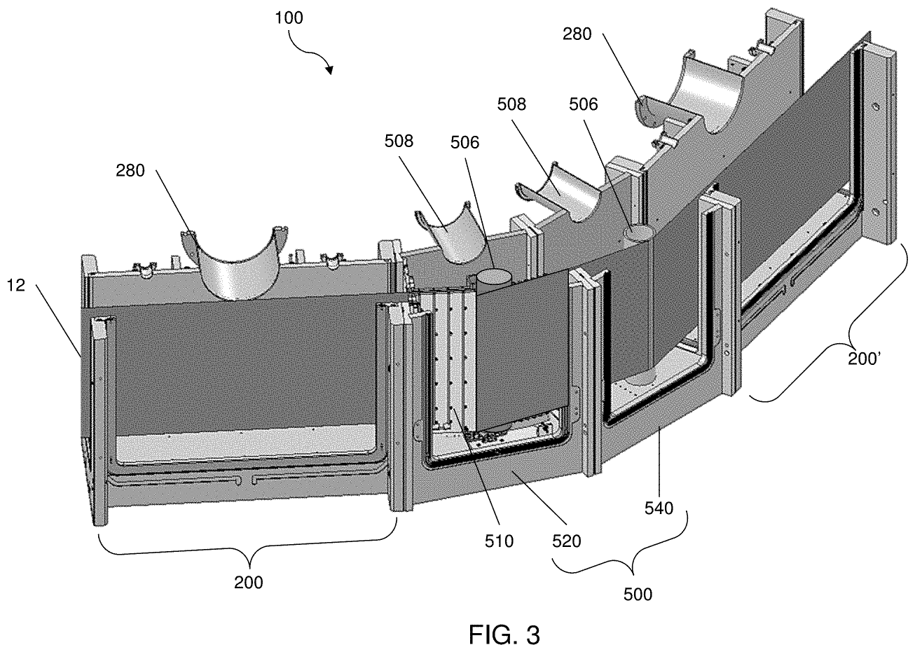

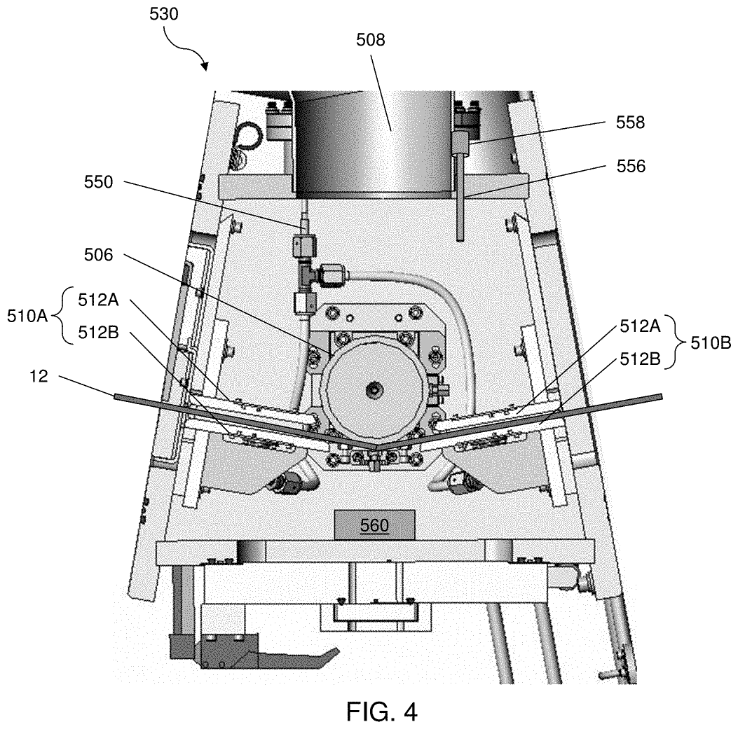

Each neighboring pair of deposition modules 200A-200F is interconnected employing a vacuum connection unit 500, which can include conductance limiters and an optional vacuum pump which enable molecular isolation while the substrate 12 passes through the vacuum connection unit 500. The vacuum connection units 500 are described in detail below with regard to FIGS. 3 and 4.

The input module 102 can be connected to deposition module 200A employing a sealing connection unit 97. The last deposition module, such as deposition module 200F, can be connected to the output module 800 employing another sealing connection unit 97. The sealing connection unit 97 may comprise a sealing unit as described in U.S. Pat. No. 9,303,316, issued on Apr. 5, 2016, incorporated herein by reference in its entirety, or any other suitable sealing unit.

The substrate 12 can be a metallic or polymer web foil that is fed into a system of deposition modules 200A-200F as a web for deposition of material layers thereupon to form the photovoltaic cell 10. The substrate 12 can be fed from an entry side (i.e., at the input module 102), continuously move through the apparatus 100 without stopping, and exit the apparatus 100 at an exit side (i.e., at the output module 800). The substrate 12, in the form of a web, can be provided on an input spool 110 provided in the input module 102.

The substrate 12, such as a metal or polymer web foil, is moved throughout the apparatus 100 by input-side rollers 120, output-side rollers 820, and additional rollers (not shown) in the vacuum connection units 500, and/or sealing connection units 97, or other devices. Additional guide rollers may be used. Some rollers (120, 820) may be bowed to spread the web (i.e., the substrate 12), some may move to provide web steering, some may provide web tension feedback to servo controllers, and others may be mere idlers to run the web in desired positions.

The input module 102 can be configured to allow continuous feeding of the substrate 12 by adjoining multiple foils by welding, stapling, or other suitable means. Rolls of substrates 12 can be provided on multiple input spools 110. A joinder device 130 can be provided to adjoin an end of each roll of the substrate 12 to a beginning of the next roll of the substrate 12. In one embodiment, the joinder device 130 can be a welder or a stapler. An accumulator device (not shown) may be employed to provide continuous feeding of the substrate 12 into the apparatus 100 while the joinder device 130 adjoins two rolls of the substrate 12.

In one embodiment, the input module 102 may perform pre-processing steps. For example, a pre-clean process may be performed on the substrate 12 in the input module 102. In one embodiment, the substrate 12 may pass by a heater array (not shown) that is configured to provide at least enough heat to remove water adsorbed on the surface of the substrate 12. In one embodiment, the substrate 12 can pass over a roller configured as a cylindrical rotary magnetron. In this case, the front surface of substrate 12 can be continuously cleaned by DC, AC, or RF sputtering as the substrate 12 passes around the roller/magnetron. The sputtered material from the substrate 12 can be captured on a disposable shield. Optionally, another roller/magnetron may be employed to clean the back surface of the substrate 12. In one embodiment, the sputter cleaning of the front and/or back surface of the substrate 12 can be performed with linear ion guns instead of magnetrons. Alternatively or additionally, a cleaning process can be performed prior to loading the roll of the substrate 12 into the input module 102. In one embodiment, a corona glow discharge treatment may be performed in the input module 102 without introducing an electrical bias.

The output module 800 can include a cutting apparatus 840. The coated substrate 12 can be fed into the cutting apparatus 840 in the output module 800 and can be cut into discrete sheets of photovoltaic cells 10. In the alternative, the output module may contain an output spool (not shown) to roll up the web 12. The discrete sheets of photovoltaic cells 10 (e.g., solar cells) are then interconnected using interconnects to form a photovoltaic panel (i.e., a solar module) which contains an electrical output.

In one embodiment, the substrate 12 may be oriented in one direction in the input module 102 and/or in the output module 800, and in a different direction in deposition modules 200A-200F. For example, the substrate 12 can be oriented generally horizontally in the input module 102 and the output module 800, and generally vertically in deposition module(s) 200A-200F. A turning roller or turn bar (not shown) may be provided to change the orientation of the substrate 12, such as between the input module 102 and the first deposition module 200A. In an illustrative example, the turning roller or the turn bar in the input module can be configured to turn the web substrate 12 from an initial horizontal orientation to a vertical orientation. Another turning roller or turn bar (not shown) may be provided to change the orientation of the substrate 12, such as between the last deposition module (such as deposition module 200F) and the output module 800. In an illustrative example, the turning roller or the turn bar in the input module 102 can be configured to turn the web substrate 12 from the vertical orientation employed during processing in deposition modules 200A-200F to a horizontal orientation.

The input spool 110 and cutting apparatus 840 or output spool may be actively driven and controlled by feedback signals to keep the substrate 12 in constant tension throughout the apparatus 100. In one embodiment, the input module 102 and the output module 800 can be maintained in the air ambient at all times while deposition modules 200A-200F are maintained at vacuum during layer deposition.

Deposition modules 200A-200F can deposit a respective material layer to form the photovoltaic cell 10 (shown in FIG. 1) as the substrate 12 passes through deposition modules 200A-200F sequentially. Modules 102, and 200A-200F may each comprise one or more heaters 270 configured to heat the substrate 12 to a corresponding appropriate deposition temperature.

Deposition module 200A may include a sputtering target 210 configured to sputter a metal precursor layer of a diffusion barrier, such as titanium precursor layer onto a front side of the substrate 12. As discussed in detail below with respect to FIGS. 3 and 4, the titanium precursor layer may be at least partially nitrided while passing through the vacuum connection unit 500 between deposition modules 200A and 200B, in order to form a diffusion barrier 22 containing titanium nitride that reduces the diffusion of chromium species through the diffusion barrier 22.

The substrate 12 may then be provided to deposition module 200B. Deposition module 200B may include a sputtering target 212 configured to sputter a back side protective layer 25 on the back side of the substrate 12. For example, the sputtering target 212 may include a metal such as molybdenum or the like. The sputtering target 212 and heater 270 of deposition module 200B may be arranged on opposite sides of the substrate 12, as compared to similar elements of deposition modules 200A and 200C-200F. As noted above, the protective layer 25 may comprise at least one metal layer intentionally doped with at least one of oxygen or nitrogen. The oxygen or nitrogen doping may be achieved by sputtering a metal target, such as a molybdenum target, in a sputtering atmosphere comprising at least 10% (molar percent), for example at least 20%, of oxygen-containing and/or nitrogen-containing gas. In the alternative, sputtering target 212 may be a molybdenum-oxygen target.

Alternatively or additionally, one or more deposition modules (not shown) may be added between deposition modules 200A and 200E to sputter one or more adhesion layers between the first electrode 20 and the p-doped semiconductor layer 30 including a chalcogen-containing compound semiconductor material.

Deposition module 200C includes one or more sputtering targets 214 that include the materials used to form the first electrode 20 of the photovoltaic cell 10 illustrated in FIG. 1. For example, the at least one sputtering target 214 can include a molybdenum target, a molybdenum-sodium target, a molybdenum-oxygen target, and/or a molybdenum-sodium-oxygen target, as described in U.S. Pat. No. 8,134,069. In one embodiment, the at least one sputtering target 214 can be mounted on dual cylindrical rotary magnetron(s), or planar magnetron(s) sputtering targets, or RF sputtering targets. The heater 270 of deposition module 200C may operate to heat the web substrate 12 to an optimal temperature for deposition of the first electrode 20. In one embodiment, submodules containing a plurality of first sputtering targets 214 and a plurality of heaters 270 may be employed in deposition module 200C.

The portion of the substrate 12 on which the first electrode 20 is deposited is moved into deposition module 200D. A p-doped chalcogen-containing compound semiconductor material is deposited to form the p-doped semiconductor layer 30, such as a sodium doped CIGS absorber layer. In one embodiment, the p-doped chalcogen-containing compound semiconductor material can be deposited employing reactive alternating current (AC) magnetron sputtering in a sputtering atmosphere that includes argon and a chalcogen-containing gas at a reduce pressure. In one embodiment, multiple metallic component targets 216 including the metallic components of the p-doped chalcogen-containing compound semiconductor material can be provided in deposition module 200D.

As used herein, the “metallic components” of a chalcogen-containing compound semiconductor material refers to the non-chalcogenide components of the chalcogen-containing compound semiconductor material. For example, in a copper indium gallium selenide (CIGS) material, the metallic components include copper, indium, and gallium. The metallic component targets 216 can include an alloy of all non-metallic materials in the chalcogen-containing compound semiconductor material to be deposited. For example, if the chalcogen-containing compound semiconductor material is a CIGS material, the metallic component targets 216 can include an alloy of copper, indium, and gallium. More than two targets 216 may be used. The heater 270 of deposition module 200D can be a radiation heater that maintains the temperature of the web substrate 12 at the deposition temperature, which can be in a range from 200° C. to 800° C., such as a range from 200° C. to 700° C., which is preferable for CIGS deposition.

At least one chalcogen-containing gas source 320 (such as a selenium evaporator) and at least one gas distribution manifold 322 can be provided on deposition module 200D to provide a chalcogen-containing gas into deposition module 200D. While FIG. 2 schematically illustrates deposition module 200D as including two metallic component targets 216, a single chalcogen-containing gas source 320, and a single gas distribution manifold 322, multiple instances of the chalcogen-containing gas source 320 and/or the gas distribution manifold 322 can be provided in deposition module 200D.

The chalcogen-containing gas provides chalcogen atoms that are incorporated into the deposited chalcogen-containing compound semiconductor material. For example, if a CIGS material is to be deposited for the p-doped semiconductor layer 30, the chalcogen-containing gas may be selected, for example, from hydrogen selenide (H₂Se) and selenium vapor. In case the chalcogen-containing gas is hydrogen selenide, the chalcogen-containing gas source 320 can be a cylinder of hydrogen selenide. In case the chalcogen-containing gas is selenium vapor, the chalcogen-containing gas source 320 can be a selenium evaporator, such as an effusion cell that can be heated to generate selenium vapor.

The chalcogen incorporation during deposition of the chalcogen-containing compound semiconductor material determines the properties and quality of the chalcogen-containing compound semiconductor material in the p-doped semiconductor layer 30. When the chalcogen-containing gas is supplied in the gas phase at an elevated temperature, the chalcogen atoms from the chalcogen-containing gas can be incorporated into the deposited film by absorption and subsequent bulk diffusion. This process is referred to as chalcogenization, in which complex interactions occur to form the chalcogen-containing compound semiconductor material. The p-type doping in the p-doped semiconductor layer 30 is induced by controlling the degree of deficiency of the amount of chalcogen atoms with respect the amount of non-chalcogen atoms (such as copper atoms, indium atoms, and gallium atoms in the case of a CIGS material) deposited from the metallic component targets 216.

In one embodiment, each metallic component target 216 can be employed with a respective magnetron (not expressly shown) to deposit a chalcogen-containing compound semiconductor material with a respective composition. In one embodiment, the composition of the metallic component targets 216 can be gradually changed along the path of the substrate 12 so that a graded chalcogen-containing compound semiconductor material can be deposited in deposition module 200D. For example, if a CIGS material is deposited as the chalcogen-containing compound semiconductor material of the p-doped semiconductor layer 30, the atomic percentage of gallium of the deposited CIGS material can increase as the substrate 12 progresses through deposition module 200D. In this case, the p-doped CIGS material in the p-doped semiconductor layer 30 of the photovoltaic cell 10 can be graded such that the band gap of the p-doped CIGS material increases with distance from the interface between the first electrode 20 and the p-doped semiconductor layer 30.

In one embodiment, the total number of metallic component targets 216 may be in a range from 3 to 20. In an illustrative example, the composition of the deposited chalcogen-containing compound semiconductor material (e.g., the p-doped CIGS material absorber 30) can be graded such that the band gap of the p-doped CIGS material varies (e.g., increases or decreases gradually or in steps) with distance from the interface between the first electrode 20 and the p-doped semiconductor layer 30. For example, the band gap can be about 1 eV at the interface with the first electrode 20, and can be about 1.3 eV at the interface with subsequently formed n-doped semiconductor layer 40.

Deposition module 200D includes a deposition system for deposition of a chalcogen-containing compound semiconductor material for forming the p-doped semiconductor layer 30. As discussed above, the deposition system includes a vacuum enclosure attached to a vacuum pump 280, and a sputtering system comprising at least one sputtering target (such as the at least one metallic component target 216, for example a Cu—In—Ga target) located in the vacuum enclosure and at least one respective magnetron. The sputtering system is configured to deposit a material including at least one component of a chalcogen-containing compound semiconductor material (i.e., the non-chalcogen metallic component(s) of the chalcogen-containing compound semiconductor material) over the substrate 12 in the vacuum enclosure. In other words, deposition module 200D is a reactive sputtering module in which the chalcogen gas (e.g., selenium vapor) from gas distribution manifolds 322 reacts with the metal (e.g., Cu—In—Ga) sputtered from the targets 216 to form the chalcogen-containing compound semiconductor material (e.g., CIGS) layer 30 over the substrate 12.

In an illustrative example, the chalcogen-containing compound semiconductor material can comprise a copper indium gallium selenide, and the at least one sputtering target (i.e., the metallic component targets 216) can comprise materials selected from copper, indium, gallium, and alloys thereof (e.g., Cu—In—Ga alloy, CIG). In one embodiment, the chalcogen-containing gas source 320 can be configured to supply a chalcogen-containing gas selected from gas phase selenium and hydrogen selenide (H₂Se). In one embodiment, the chalcogen-containing gas can be gas phase selenium, i.e., vapor phase selenium, which is evaporated from a solid source in an effusion cell.

While the present disclosure is described employing an embodiment in which metallic component targets 216 are employed in deposition module 200D, embodiments are expressly contemplated herein in which each, or a subset, of the metallic component targets 216 is replaced with a pair of two sputtering targets (such as a copper target and an indium-gallium alloy target), or with a set of three supper targets (such as a copper target, an indium target, and a gallium target).

Generally speaking, the chalcogen-containing compound semiconductor material can be deposited by providing a substrate 12 in a vacuum enclosure attached to a vacuum pump 380, providing a sputtering system comprising at least one sputtering target 216 located in the vacuum enclosure and at least one respective magnetron located inside a cylindrical target 216 or behind a planar target (not explicitly shown), and providing a gas distribution manifold 322 having a supply side and a distribution side. The chalcogen-containing compound semiconductor can be deposited by sputtering a material including at least one component (i.e., the non-chalcogen component) of a chalcogen-containing compound semiconductor material onto the substrate 12, while supplying a chalcogen-containing gas (e.g., Se vapor) to the vacuum chamber through the gas distribution manifold 322.

The portion of the substrate 12 on which the first electrode 20 and the p-doped semiconductor layer 30 are deposited is subsequently passed into deposition module 200E. An n-doped semiconductor material is deposited in deposition module 200E to form the n-doped semiconductor layer 40 illustrated in the photovoltaic cell 10 of FIG. 1. Deposition module 200E can include, for example, a sputtering target 218 (e.g., a CdS target) and a magnetron (not expressly shown). The sputtering target 218 can include, for example, a rotary or planar magnetron powered by AC, RF, DC or Pulsed DC.

The portion of the substrate 12 on which the first electrode 20, the p-doped semiconductor layer 30, and the n-doped semiconductor layer 40 are deposited is subsequently passed into deposition module 200F. A transparent conductive oxide material is deposited in deposition module 200F to form the second electrode comprising a transparent conductive layer 50 illustrated in the photovoltaic cell 10 of FIG. 1. Deposition module 200F can include, for example, a fourth sputtering target 220 and a magnetron (not expressly shown). The fourth sputtering target 220 can include, for example, a ZnO, AZO or ITO target and a rotary or planar magnetron powered by AC, RF, DC or Pulsed DC. A transparent conductive oxide layer 50 is deposited over the material stack 30, 40 including the p-n junction. In one embodiment, the transparent conductive oxide layer 50 can comprise a material selected from tin-doped indium oxide, aluminum-doped zinc oxide, and zinc oxide. In one embodiment, the transparent conductive oxide layer 50 can have a thickness in a range from 60 nm to 1,800 nm.

Subsequently, the web substrate 12 passes into the output module 800. The substrate 12 can be sliced into photovoltaic cells using a cutting apparatus 840, or can be wound onto an output spool (not shown).

### Barrier Layer Formation Systems

FIG. 3 is a perspective view of adjacent deposition modules 200 and 200′ and a connection unit 500 of the modular deposition apparatus 100, when arranged in a non-linear configuration such that the substrate 12 curves by more than about 5° between adjacent deposition modules, according to various embodiments of the present disclosure. Deposition modules 200, 200′ may be any adjacent ones of deposition modules 200A-200F. For example, module 200 may correspond to module 200A and module 200′ may correspond to module 200B of FIG. 2.

Referring to FIG. 3, deposition modules 200, 200′ are shown to be disposed at a non-zero angle, e.g., an angle ranging from 10° to 40°, such as from 25° to 35°, or from 27° to 32°, with respect to an adjacent deposition module, such that the substrate 12 moves through deposition modules 200, 200′ in different directions. However, any and/or all modules 200A-200F, included in the apparatus 100 may be disposed in a similar angular arrangement with a non-zero angle and a vacuum connection unit 500 disposed therebetween.

The vacuum connection unit 500 may be configured to bend the substrate 12, such that the substrate 12 is aligned with deposition module 200′, after exiting deposition module 200. The first vacuum chamber 520 may be disposed adjacent to deposition module 200A, and the second vacuum chamber 540 may be disposed adjacent to deposition module 200B. While the connection unit 500 is shown to include two vacuum chambers 520, 540, the present disclosure is not limited thereto. For example, in other embodiments, a single vacuum chamber or three or more vacuum chambers may be included in the connection unit 500.

The vacuum connection unit 500 may include a roller 506 or roller assembly in each of the first and second chambers 520, 540. The rollers 506 may both be configured to bend the substrate 12 to change the direction of the substrate 12. Each vacuum chamber 520, 540 may also include a vacuum pump 508, (shown schematically in FIG. 3 as a cut away portion of vacuum pump conduit or housing) to maintain vacuum conditions therein. The connection unit may also include one or more conductance limiters 510 (e.g., parallel plate limiters).

FIG. 4 is a top view of a modified vacuum chamber 530 that may be included in one of the connection units 500, as either vacuum chamber 520 or 540. In particular, vacuum chamber 530 may comprise the vacuum chamber 540 of the connection unit 500 disposed between deposition modules 200A and 200B.

As shown in FIG. 4, the vacuum chamber 530 may include a first conductance limiter 510A, a second conductance limiter 510B, an inert gas line 550, a nitriding gas line 556, and a mass flow controller 558 (e.g., mass flow control valve). The conductance limiters 510A, 510B may each include opposing first and second plates 512A, 512B. A gap between the plates 512A, 512B of the first conductance limiter 510A may be greater than a gap between the plates 512A, 512B of the second conductance limiter 510B.

The substrate 12 may pass through the gap of the first conductance limiter 510A when entering the vacuum chamber 530, and may pass through the gap of the second conductance limiter 510B when exiting the vacuum chamber 530. Accordingly, the conductance limiters 510A, 510B may be configured to reduce molecular flow into and out of the vacuum chamber 530 (e.g., vacuum chamber 540).

The inert gas line 550 may be fluidly connected to both conductance limiters 510A, 510B and an inert gas source (not shown). Accordingly, the inert gas line 550 may be configured to provide an inert gas, such as argon, helium, or neon, into the gaps of the conductance limiters 510A, 510B. Accordingly, the inert gas may operate to further limit molecular flow into and out of the vacuum chamber 530.

The nitriding gas line 556 may fluidly connect the mass flow controller 558 to a nitriding gas source (not shown). For example, the nitriding gas may be nitrogen gas or a nitrogen-rich gas such as ammonia. The mass flow controller 558 may operate to control an amount of nitriding gas that is supplied to vacuum chamber 530. Accordingly, as the substrate 12 passes through vacuum chamber 530, the diffusion barrier 22 of substrate 12 is exposed to nitrogen.

In particular, referring to FIGS. 1, 2, and 4, the titanium precursor layer of the diffusion barrier 22 formed in module 200A is exposed to nitrogen while passing through vacuum chamber 530, in order to convert at least some of the titanium into titanium nitride. In addition, the substrate 12 and/or diffusion barrier 22 remain at a temperature of at least about 200° C., such as at least 550° C., due to heating by the heater 270 of a proceeding deposition module, such as deposition module 200A. In other embodiments, the vacuum chamber 530 may include an optional heater 560, such as a radiant heater, to maintain the diffusion barrier 22 at a temperature sufficient for nitriding the diffusion barrier 22, such as a temperature above 200° C., such as a temperature of at least 500° C. (e.g., a temperature ranging from 550-700° C.).

Accordingly, the nitrogen reacts with the titanium precursor layer of the diffusion barrier 22, such that at least a portion of the outer surface of the titanium precursor layer of the diffusion barrier 22 is converted into a titanium nitride (e.g., TiₓN, where 1≤x≤2, e.g., TiN and/or Ti₂N) film. In some embodiments, the flow rate of the nitriding gas may range from about 50 to about 1000 sccm, such as from about 75 to about 800 sccm, or from about 100 to about 500 sccm, and the diffusion barrier 22 may be exposed to the nitriding gas for a time period ranging from about 30 second to about 10 minutes, such as from about 45 seconds to about 5 minutes, or from about 50 seconds to about 2 minutes, such as about 1 minute, while passing through the vacuum chamber 530. In some embodiments, the flow rate of the nitriding gas may be configured such that the diffusion barrier 22 includes a graded TiₓN composition, with a decreasing nitrogen content as distance to the substrate 12 decreases, or may be configured to convert all or a part of the titanium precursor layer of the diffusion barrier 22 (e.g., 25-50%) into TiₓN.

### Photovoltaic Cell Formation Methods

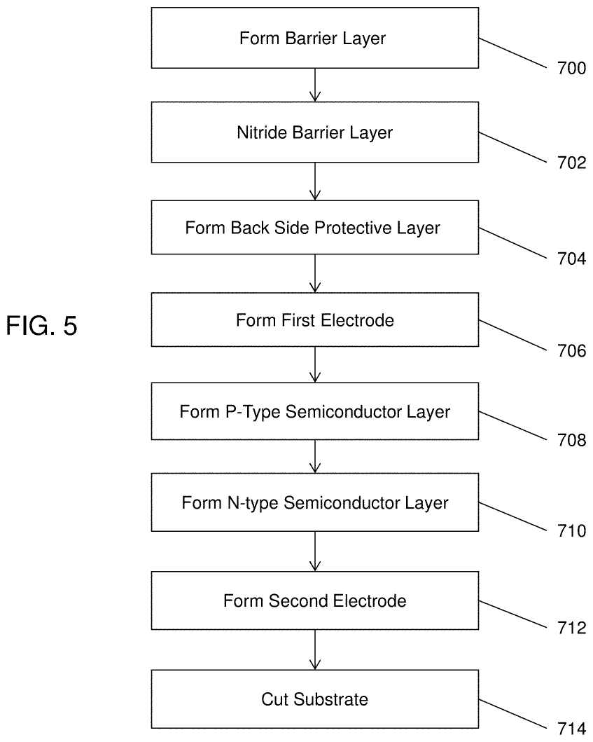

FIG. 5 is a block diagram illustrating a method of forming a photovoltaic cell, according to various embodiments of the present disclosure. Referring to FIGS. 1, 2, 4, and 5, in step 700, the method may include providing the substrate 12 to a first deposition module 200A, via a sealing connection unit 97, and forming a titanium precursor layer of the diffusion barrier 22 on a front side of the substrate 12. In particular, the substrate 12 may be a steel substrate supplied from an input spool in an input module 102 to deposition module 200A. In particular, the substrate 12 may be moved through a sealing connection unit 97 connecting the input module 102 to deposition module 200A. Deposition module 200A may include a sputtering target, such as a titanium target, configured to sputter the titanium precursor layer of the diffusion barrier 22 onto the substrate 12 as the substrate 12 moves through deposition module 200A.

In step 702, the method may include nitriding all or a part of the titanium precursor layer of the diffusion barrier 22. In particular, the substrate 12 may be moved through a vacuum connection unit 500 including a vacuum chamber 530 and that connects deposition module 200A to deposition module 200B. A nitriding gas may be pumped into the vacuum chamber 530, as the substrate 12 passes there through. A movement speed of the substrate 12 and a flow rate of the nitriding gas may be controlled, such that at least a portion of the titanium precursor layer of the diffusion barrier 22 is converted into titanium nitride, as discussed above. For example, the titanium precursor layer of the diffusion barrier 22 may be completely converted into titanium nitride, or a titanium nitride film may be formed from a surface portion of the titanium precursor layer of the diffusion barrier 22 such that the diffusion barrier 22 contains an upper titanium nitride layer 22B and a lower titanium layer 22A between the substrate 12 and the upper titanium nitride layer 22B. The substrate 12 may be maintained above a temperature of at least about 200° C., such as at least about 550° C., during step 702. For example, the substrate 12 may remain above 550° C., due to heating in deposition module 200B and/or the substrate 12 may be heated by a heater 560 disposed in vacuum chamber 530.

In step 704, the method may include forming a protective layer 25 on a back side of the substrate 12. In particular, the substrate 12 may be provided from the vacuum chamber 530 to deposition module 200B. Deposition module 200B may include a metal sputtering target used to sputter the protective layer 25 on the backside of the substrate 12. The sputtering may occur in the presence of oxygen and/or nitrogen, such that the protective layer 25 may include from 15-50 atomic percent of oxygen, nitrogen, or a combination thereof. In some embodiments, the protective layer 25 may be omitted and step 704 may not be performed.

In step 706, the method may include forming a first electrode 20 on the diffusion barrier 22. In particular, the substrate 12 may be provided to deposition module 200C and the alkali diffusion barrier 24, first transition metal layer 26, and/or the second transition metal layer 28 may be formed by changing the processing parameters in the deposition module 200C, or in a plurality of submodules of the deposition module 200C.

In step 708, a p-doped semiconductor layer 30 (i.e., an absorber layer) may be formed on the first electrode 20. For example, the absorber layer 30 may be deposited on the substrate 12, while the substrate 12 moves through deposition module 200D.

In step 710, an n-doped semiconductor layer 40 may be formed on the absorber layer 30. For example, the n-doped semiconductor layer 40 may be deposited on the substrate 12, while the substrate 12 moves through deposition module 200E.

In step 712, a second electrode 50 may be formed on the n-doped semiconductor layer 40. For example, the second electrode 50 may be deposited on the substrate 12 while the substrate moves through deposition module 200F.

In step 714, the substrate 12 may be cut into individual photovoltaic cells. In particular, the substrate 12 may be provided from a deposition module 200F to an output module 800 including a substrate cutter, via a sealing connection unit 97. The sealing connection unit may include isolation chambers connected by parallel plate conductance limiters including one or more magnetic substrate guides, to prevent damage to the front surface of the substrate, as described above.

The method may optionally include additional steps in which additional layers may be formed on the substrate 12. For example, an anti-reflection layer may be formed on the second electrode 50.

While sputtering was described as the preferred method for depositing all layers onto the substrate, some layers may be deposited by MBE, CVD, evaporation, plating, etc.

It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the photovoltaic cells of the present invention.

What is claimed is:

1. A thin film deposition system configured to form a photovoltaic cell on a moving substrate, the system comprising:
a first deposition module comprising a titanium sputtering target and configured to deposit a titanium precursor layer of a diffusion on the substrate as the substrate moves through the first deposition module;
a second deposition module configured to deposit a first electrode onto the diffusion barrier as the substrate moves through the second deposition module; and
a first connection unit configured to nitride at least a portion of the titanium precursor layer of the diffusion barrier, while the substrate moves though the first connection unit from the first deposition module to the second deposition module.

2. The system of claim 1, wherein the nitriding converts at least a portion of the titanium precursor layer of the diffusion barrier into titanium nitride.

3. The system of claim 1, wherein the first connection unit comprises:
a first gas supply line configured to supply a nitrogen-rich gas to the first connection unit; and
a mass flow controller configured to control a flow rate of the nitrogen-rich gas through the first supply line.

4. The system of claim 3, wherein the nitrogen-rich gas comprises nitrogen gas or ammonia.

5. The system of claim 3, wherein mass flow controller is configured to provide a flow rate of the nitrogen-rich gas that ranges from about 50 standard cubic centimeters per minute (sccm) to about 800 sccm.

6. The system of claim 1, wherein the first connection unit comprises a heater configured to maintain the substrate at a temperature of at least about 550° C.

7. The system of claim 1, wherein the first deposition module comprises a heater configured to heat the substrate to a temperature of at least about 200° C.

8. The system of claim 1, wherein the first connection unit comprises:
a vacuum pump configured to maintain vacuum conditions within the first connection unit; and
at least one roller configured to bend the substrate.

9. The system of claim 1, wherein the first connection unit comprises:
a first conductance limiter comprising parallel plates configured to allow the substrate to enter the first connection unit by passing therebetween;
a second conductance limiter comprising parallel plates configured to allow the substrate to exit the first connection unit; and
an inert gas supply line configured to provide an inert gas to the first and second parallel plate conductance limiters.

10. The system of claim 9, wherein a gap between the parallel plates of the first conductance limiter is greater than a gap between the parallel plates of the second conductance limiter.

11. The system of claim 10, wherein the second deposition module comprises at least a molybdenum sputtering target and a sodium-doped molybdenum sputtering target.

12. The system of claim 1, further comprising
a third deposition module configured to form a p-doped semiconductor layer on the first electrode;
a fourth deposition module configured to form an n-doped semiconductor layer on the p-type semiconductor layer;
a fifth deposition module configured to form a second electrode on the n-doped semiconductor layer; and
additional connection units configured to transfer the substrate between the second, third, fourth, and fifth deposition modules, while maintaining vacuum conditions.

13. A sputter deposition method comprising:
depositing a titanium precursor layer onto a front side of a substrate using a first deposition module while moving the substrate through the first deposition module and heating the substrate;
transferring the substrate from the first deposition module to a second deposition module using a first connection module, while nitriding at least a portion of the titanium precursor layer to form a diffusion barrier by supplying a nitrogen-rich gas to the first connection module;
depositing a first electrode onto the diffusion barrier using the second deposition module, while moving the substrate through the second deposition module; and
depositing a p-doped semiconductor layer, an n-doped semiconductor layer, and a second electrode onto the first electrode layer, using respective additional deposition modules, while transferring the substrate between the additional deposition modules using additional connection modules configured to maintain vacuum conditions.

14. The method of claim 13, further comprising:
depositing a protective layer onto a backside of the substrate using another deposition module, after the nitriding of at least a portion of the titanium precursor layer; and
transferring the substrate to a third deposition module, using another connection unit configured to maintain vacuum conditions.

15. The method of claim 13, wherein all of the first, second, and additional deposition modules comprise sputtering targets.

16. The method of claim 13, wherein the depositing a titanium precursor layer onto a front side of a substrate comprises heating the substrate to a temperature of at least 200° C.

17. The method of claim 13, wherein the transferring the substrate from the first deposition module to a second deposition module comprises using a heater disposed in the first connection unit to maintain the substrate at a temperature of at least 550° C.

18. The method of claim 13, wherein:
the depositing a first electrode onto the diffusion barrier comprises using at least a molybdenum sputtering target and a sodium-doped molybdenum sputtering target; and
the supplying a nitrogen-rich gas to the first connection module comprises supplying nitrogen gas or ammonia to the connection unit at a flow rate ranging from about 50 standard cubic centimeters per minute (sccm) to about 800 sccm.

19. The method of claim 13, wherein the nitriding at least a portion of the titanium precursor layer comprises nitriding a portion of the titanium precursor layer, such that the diffusion barrier comprises an upper titanium nitride layer and a lower titanium layer disposed between the substrate and the upper titanium nitride layer.

20. A photovoltaic cell comprising:
a metal substrate having a front side and a back side;
a protective layer disposed on the back side of the substrate;
a diffusion barrier comprising titanium nitride disposed on the front side of the substrate;
a first electrode comprising a first molybdenum layer, a second molybdenum layer, and a sodium-doped molybdenum layer disposed between the first and second molybdenum layers;
a p-doped semiconductor layer disposed on the first electrode;
an n-doped semiconductor layer disposed on the p-doped semiconductor layer; and
a second electrode disposed on the n-doped semiconductor layer.
